(19) United States
(12) Patent Application Publication
(10) Pub. No.: US 2026/0305013 A1
(43) Pub. Date: Oct. 1, 2026

(54) METHOD FOR PACKAGING SEMICONDUCTOR DEVICE

(71) Applicant: OIP Technology Pte Ltd, Singapore (SG)

(72) Inventors: How Yuan HWANG, Singapore (SG); Yonggang JIN, Singapore (SG)

(21) Appl. No.: 19/632,718

(22) Filed: Mar. 30, 2026

(30) Foreign Application Priority Data
Mar. 31, 2025 (CN) 202510389255.X

(51) Int. Cl. H10F 77/50; H10F 77/00

(52) U.S. Cl. CPC H10F 77/50; H10F 77/933

(57) ABSTRACT

The present invention provides a method for packaging a semiconductor device. The method includes: providing a substrate chip having a front side and an opposing backside; forming photoelectric conversion modules at spacings on the front side of the substrate chip, which are connected to the substrate chip by vias; forming protective caps on the front side of the substrate chip between adjacent photoelectric conversion modules, each protective cap having inner surfaces and outer surfaces, inner surfaces together defining a cavity; forming an encapsulation layer over the front side of the substrate chip, which fills gaps between photoelectric conversion modules, and from which surfaces of the photoelectric conversion modules are exposed; cutting protective caps and substrate chip so that each cavity is separated into two parts each having an open side; bonding the substrate chip at backside to system boards; and plugging pluggable optical array modules into cavities from open sides.

### CROSS-REFERENCES TO RELATED APPLICATION

This application claims the priority of Chinese patent application number 202510389255.X, filed on Mar. 31, 2025, the entire contents of which are incorporated herein by reference.

### TECHNICAL FIELD

The present invention relates to semiconductor packaging technology and, in particular, to a method for packaging a semiconductor device.

### BACKGROUND

Chip-on-substrate (CoS) is an advanced packaging technique that involves directly mounting a chip onto a substrate, providing high-density interconnectivity and efficient heat dissipation. For example, there are photoelectric conversion modules mounted on a silicon photonic chip (substrate chip).

In some applications, a pluggable optical array module may be additionally coupled to photoelectric conversion modules to provide more powerful photoelectric conversion. Conventionally, integrating a pluggable optical array module and a semiconductor device within a single package is accomplished by connecting, through metal wire bonding, the pluggable optical array module to a silicon photonic chip, and hence to photoelectric conversion modules arranged on the silicon photonic chip.

However, the conventional use of metal wire bonding is not compatible with subsequent surface-mounting processes and leads to the pluggable optical array module being exposed and therefore unprotected against moisture and possible damage during mechanical handling. As a consequence, the pluggable optical array module may be adversely affected by moisture and susceptible to mechanical damage caused by collisions during handling.

### SUMMARY

It is an object of the present invention to provide a method for packaging a semiconductor device, which allows the pluggable optical array module to be surface-mounted to a substrate chip and prevents it from being adversely affected by moisture and from any mechanical damage.

To this end, the present invention provides a method for packaging a semiconductor device, which includes:
providing a substrate chip having a front side and an opposing backside;
forming a plurality of photoelectric conversion modules at spacings on the front side of the substrate chip, which are connected to the substrate chip by vias, so that the front side of the substrate chip is exposed between adjacent photoelectric conversion modules;
forming protective caps on the front side of the substrate chip between adjacent photoelectric conversion modules, each protective cap having inner surfaces and outer surfaces, the inner surfaces together defining a cavity;
forming an encapsulation layer over the front side of the substrate chip, which fills gaps between the photoelectric conversion modules, and from which surfaces of the photoelectric conversion modules are exposed;
cutting, from surfaces of the protective caps, the protective caps and the substrate chip so that each cavity is separated into two parts each having an open side;
bonding the substrate chip at the backside to system boards; and
plugging pluggable optical array modules into the cavities from their open sides, thereby optically interconnecting and integrating them with the substrate chip.

Optionally, in the method, each of the photoelectric conversion modules may include a plurality of spaced functional chips, wherein the front side of the semiconductor substrate is exposed between adjacent functional chips, wherein the encapsulation layer also fills the gaps between the functional chips, and wherein the functional chips are connected by the vias to the substrate chip.

Optionally, in the method, the protective caps and the encapsulation layer may be made of the same material.

Optionally, in the method, the protective caps and the encapsulation layer may be made of a material including a resin.

Optionally, in the method, there may be optical interconnect trenches in the substrate chip between adjacent photoelectric conversion modules, which are covered by the protective caps.

Optionally, in the method, each of the optical interconnect trenches may also be separated into two parts at the same time as the protective caps and the substrate chip are cut from the surfaces of the protective caps so that each cavity is separated into two parts.

Optionally, in the method, the protective caps and the substrate chip may be cut from the surfaces of the protective caps so that each cavity is separated into two equal parts.

Optionally, in the method, the outer surfaces of each protective cap may include three outer wall surfaces, which are perpendicularly joined in succession, and the inner surfaces of each protective cap may include three inner wall surfaces, which are perpendicularly joined in succession.

Optionally, in the method, the protective caps may be pluggably or fixedly attached to optical interconnects between adjacent photoelectric conversion modules.

Optionally, in the method, the substrate chip may be soldered at the backside to the system boards with a solder material.

The present invention provides a method for packaging a semiconductor device, which includes: providing a substrate chip having a front side and an opposing backside; forming a plurality of photoelectric conversion modules at spacings on the front side of the substrate chip, which are connected to the substrate chip by vias, so that the front side of the substrate chip is exposed between adjacent photoelectric conversion modules; forming protective caps on the front side of the substrate chip between adjacent photoelectric conversion modules, each protective cap having inner surfaces and outer surfaces, the inner surfaces together defining a cavity, each outer surface being spaced apart by a gap from any adjacent photoelectric conversion module; forming an encapsulation layer over the front side of the substrate chip, which fills gaps between the photoelectric conversion modules, and from which surfaces of the photoelectric conversion modules are exposed; cutting, from surfaces of the protective caps, the protective caps and the substrate chip so that each cavity is separated into two parts each having an open side; bonding the substrate chip at the backside to system boards; and plugging pluggable optical array modules into the cavities from their open sides, thereby optically interconnecting and integrating them with the substrate chip. Thus, the present invention enables direct surface mounting of pluggable optical array modules to a substrate chip by plugging them into cavities in the substrate chip. This is compatible with subsequent surface-mounting processes. Moreover, the pluggable optical array modules are received in the cavities and protected by the protective caps against moisture and mechanical handling. Therefore, the pluggable optical array modules are prevented from being adversely affected by moisture and from any mechanical damage.

### BRIEF DESCRIPTION OF THE DRAWINGS

FIG. 1 shows a flowchart of a method for packaging a semiconductor device according to an embodiment of the present invention.

FIGS. 2 to 9 show schematic representations of a semiconductor device being packaged according to an embodiment of the present invention.

In the figures, 210 denotes a substrate chip; 220, a via; 230, a photoelectric conversion module; 231, a functional chip; 240, an optical interconnect trench; 250, a protective cap; 251, a cavity; 260, a resin layer; 270, an encapsulation layer; 280, a pluggable optical array module; 290, a system board; and 300, a solder material.

### DETAIL DESCRIPTION

Specific embodiments of the present invention will be described in greater detail below with reference to the appended schematic drawings. From the following description, advantages and features of the invention will become more apparent. Note that the figures are provided in a very simplified form not necessarily drawn to exact scale and for the only purpose of facilitating easy and clear description of the embodiments.

It is to be noted that the terms “first”, “second” and the like may be used hereunder to distinguish between similar elements without necessarily implying any particular ordinal or chronological sequence. It will be understood that the terms so used are interchangeable, whenever appropriate. Likewise, if a method is described herein as comprising a series of steps, the order of these steps as presented herein is not necessarily the only order in which they can be performed, and some of the stated steps may be omitted and/or other steps not described herein may be added to the method.

It will be understood that when a layer (or film), region, pattern or structure is referred to as being “above” a substrate, other layer (or film), region and/or pattern, it may be directly on the other layer or substrate, or intervening layer(s) may also be present. It will also be understood that when a layer is referred to as being “under” another layer, it may be directly under or below the other layer, or one or more intervening layers may also be present. Further, reference to a layer being “above” or “under” another layer is made herein based on the orientation of the accompanying drawings.

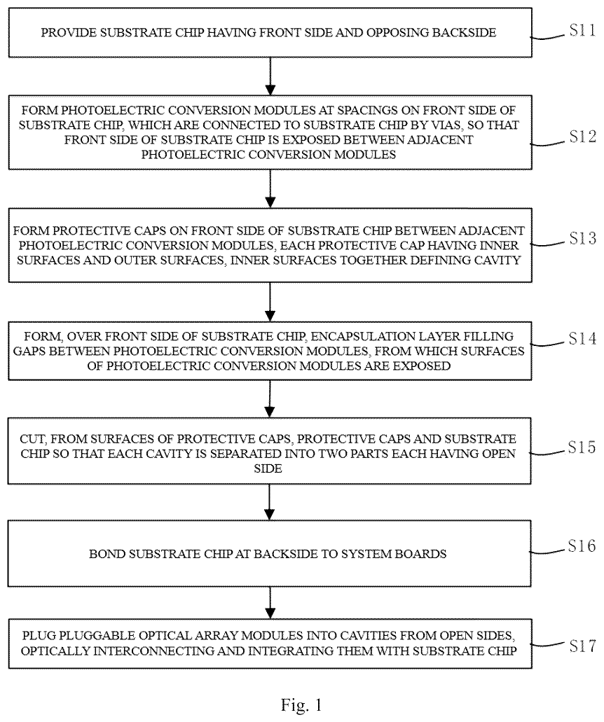

Referring to FIG. 1, the present invention provides a method for packaging a semiconductor device, which includes:
S11) providing a substrate chip having a front side and an opposing backside;
S12) forming a plurality of photoelectric conversion modules at spacings on the front side of the substrate chip, which are connected to the substrate chip by vias, so that the front side of the substrate chip is exposed between adjacent photoelectric conversion modules;
S13) forming protective caps on the front side of the substrate chip between adjacent photoelectric conversion modules, each protective cap having inner surfaces and outer surfaces, the inner surfaces together defining a cavity;
S14) forming an encapsulation layer over the front side of the substrate chip, which fills gaps between the photoelectric conversion modules, and from which surfaces of the photoelectric conversion modules are exposed;
S15) cutting, from surfaces of the protective caps, the protective caps and the substrate chip so that each cavity is separated into two parts each having an open side;
S16) bonding the substrate chip at the backside to system boards; and
S17) plugging pluggable optical array modules into the cavities from their open sides, thereby optically interconnecting and integrating them with the substrate chip.

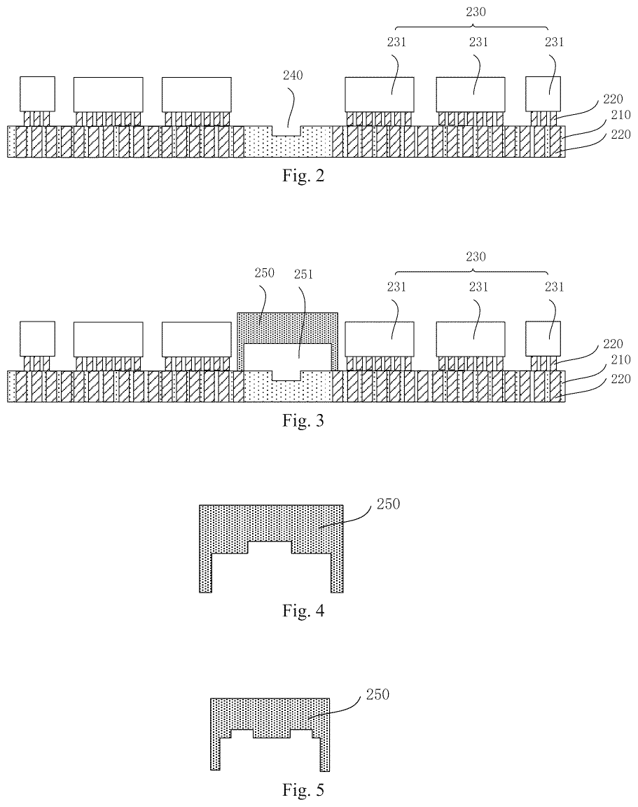

Referring to FIG. 2, first of all, a substrate chip 210 is provided, which may be a silicon photonic chip, and in which multiple spaced vias 220 may be formed. The substrate chip 210 has a front side and an opposite backside. A plurality of identical photoelectric conversion modules 230 are formed at spacings on the front side of the substrate chip 210 so that in every adjacent pair of photoelectric conversion modules 230, one of the photoelectric conversion modules 230 is located on one side of the other photoelectric conversion module 230. The photoelectric conversion modules 230 are connected to the substrate chip 210 by vias 220. In particular, the vias 220 may be spaced apart by an interlayer dielectric layer. Every adjacent pair of photoelectric conversion modules 230 may be arranged in symmetry about an axis perpendicular to a surface of the substrate chip 210. The front side of the substrate chip 210 is exposed between adjacent photoelectric conversion modules 230. Each photoelectric conversion module 230 may include a plurality of functional chips 231, which are spaced apart so that the front side of the substrate chip 210 is exposed between adjacent functional chips 231. The functional chips 231 may be connected to the substrate chip 210 by vias 220. Optical interconnect trenches 240 may be formed in the substrate chip 210 between adjacent photoelectric conversion modules 230. The optical interconnect trenches 240 may be located right in the middle between adjacent photoelectric conversion modules 230.

Subsequently, referring to FIG. 3, protective caps 250 are formed on the front side of the substrate chip 210 between adjacent photoelectric conversion modules 230. The protective caps 250 may be made of a resin. Each protective cap 250 has inner surfaces and outer surfaces, and the inner surfaces together define a cavity 251. Each outer surface is spaced apart from any adjacent photoelectric conversion module 230. The protective caps 250 may be pluggably or fixedly attached to the front side of the substrate chip 210 between adjacent photoelectric conversion modules 230. The protective caps 250 cover the optical interconnect trenches 240, optionally so that the optical interconnect trenches 240 are aligned with central portions of the protective caps 250. The shape of the protective caps 250 may vary depending on the shape of pluggable optical array modules. In a first exemplary implementation, the outer surfaces of each protective cap 250 may include three outer wall surfaces, which are perpendicularly joined in succession, and the inner surfaces of the protective cap 250 may include three inner wall surfaces, which are perpendicularly joined in succession. If the pluggable optical array modules each have a portion with a protrusion for insertion, a recess may be formed in a top one of the inner wall surfaces. If there are multiple protrusions, multiple recesses may be formed. With this arrangement, a pluggable optical array module may be subsequently inserted into the cavity, with the protrusion(s) engaging in the recess(es), facilitating retention of the pluggable optical array module. In a second exemplary implementation, referring to FIG. 4, the outer surfaces of each protective cap 250 may include three outer wall surfaces, which are perpendicularly joined in succession, and the inner surfaces of the protective cap 250 may include three inner wall surfaces, which are perpendicularly joined in succession. In this case, a single recess may be formed in a top one of the inner wall surfaces. In a third exemplary implementation, referring to FIG. 5, the outer surfaces of each protective cap 250 may include three outer wall surfaces, which are perpendicularly joined in succession, and the inner surfaces of the protective cap 250 may include three inner wall surfaces, which are perpendicularly joined in succession. In this case, two recesses may be formed in a top one of the inner wall surfaces. Therefore, the optical interconnect trenches 240 in the substrate chip 210, or the recesses in the top inner wall surfaces of the protective caps, may be configured as practically needed, and other shapes are also possible.

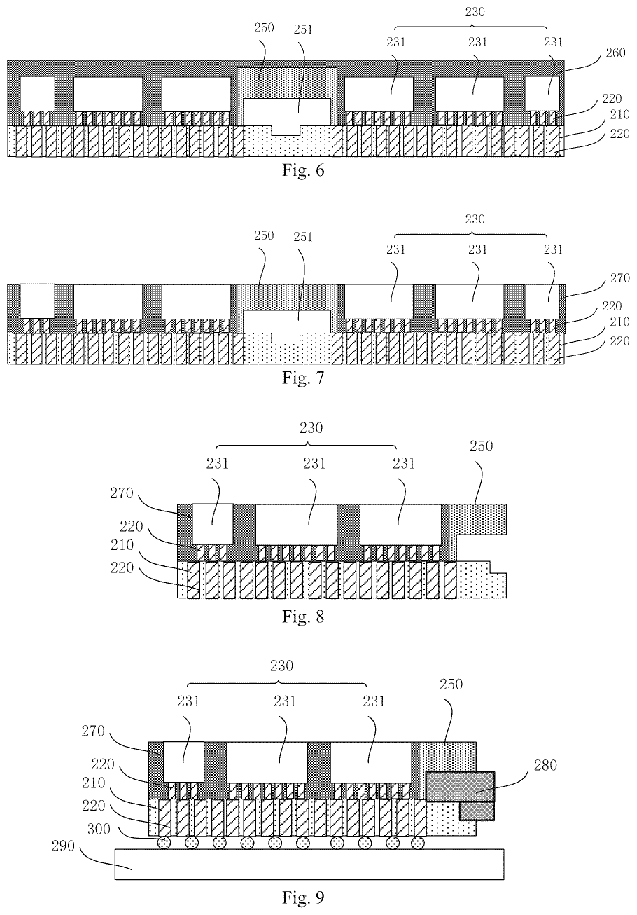

Afterwards, referring to FIG. 6, a resin layer 260 is formed over the front side of the substrate chip 210 so as to fill gaps between the photoelectric conversion modules 230, gaps between the outer surfaces of the protective caps 250 and the photoelectric conversion modules 230 and gaps between the functional chips 231. After that, referring to FIG. 7, the resin layer 260 is thinned, forming an encapsulation layer 270, from which front sides of the photoelectric conversion modules 230 and hence of the functional chips 231 are exposed. This can facilitate heat dissipation of the photoelectric conversion modules 230 (or of the functional chips). The protective caps 250 may be thinned at the same time as the resin layer 260 is thinned so that their surfaces become flush with one another. The encapsulation layer 270 fills gaps between the photoelectric conversion modules 230 and the gaps between the functional chips. The protective caps 250 and the encapsulation layer 270 may be formed of the same resin.

Next, referring to FIG. 8, the protective caps 250 and the substrate chip 210 are cut from the surfaces of the protective caps 250 until each cavity 251 is divided into two parts, each of which is open on one side. In this way, the cavities 251 are laterally exposed. Preferably, each cavity is separated into two equal parts. Meanwhile, as a result of cutting the substrate chip 210, the photoelectric conversion modules may be singulated and each become able to be integrated with a pluggable optical array module. In the case of optical interconnect trenches being formed in the substrate chip 210, each optical interconnect trench may also be divided into two equal parts. Thus, after the cavities are laterally exposed, pluggable optical array modules may be plugged and unplugged therein and therefrom. Moreover, each divided part of the substrate chip has an exposed side wall surface, and each divided part of each optical interconnect trench has a stepped shape, which is complementary to the shape of a pluggable optical array module to be plugged therein, allowing the pluggable optical array modules to be mated with the semiconductor device with an increased degree of geometric matching.

After that, referring to FIG. 9, the substrate chip is bonded at the backside to system boards 290. In particular, the substrate chip may be soldered at the backside to the system boards 290 with a solder material 300. This enables the protective caps 250 and the encapsulation layer 270 to protect pluggable optical array modules 280 against moisture or possible damage during handling. Pluggable optical array modules 280 are then plugged into the cavities 251 from their open sides and thereby integrated with the substrate chip 210.

In summary, embodiments disclosed herein provide a method for packaging a semiconductor device, which includes: providing a substrate chip having a front side and an opposing backside; forming a plurality of photoelectric conversion modules at spacings on the front side of the substrate chip, which are connected to the substrate chip by vias, so that the front side of the substrate chip is exposed between adjacent photoelectric conversion modules; forming protective caps on the front side of the substrate chip between adjacent photoelectric conversion modules, each protective cap having inner surfaces and outer surfaces, the inner surfaces together defining a cavity; forming an encapsulation layer over the front side of the substrate chip, which fills gaps between the photoelectric conversion modules, and from which surfaces of the photoelectric conversion modules are exposed; cutting, from surfaces of the protective caps, the protective caps and the substrate chip so that each cavity is separated into two parts each having an open side; bonding the substrate chip at the backside to system boards; and plugging pluggable optical array modules into the cavities from their open sides, thereby optically interconnecting and integrating them with the substrate chip. Thus, the present invention enables direct surface mounting of pluggable optical array modules to a substrate chip by plugging them into cavities in the substrate chip. This is compatible with subsequent surface-mounting processes. Moreover, the pluggable optical array modules are received in the cavities and protected by the protective caps against moisture and mechanical handling. Therefore, the pluggable optical array modules are prevented from being adversely affected by moisture and from any mechanical damage.

Presented above are merely a few preferred embodiments described herein, which do not limit the invention in any way. Changes in any forms made to the principles and teachings disclosed herein, including equivalents and modifications, by any person of ordinary skill in the art without departing from the scope of the invention are intended to fall within the scope of the invention.

What is claimed is:

1. A method for packaging a semiconductor device, comprising:
providing a substrate chip having a front side and an opposing backside;
forming a plurality of photoelectric conversion modules at spacings on the front side of the substrate chip, wherein the plurality of photoelectric conversion modules are connected to the substrate chip by vias, so that the front side of the substrate chip is exposed between adjacent photoelectric conversion modules;
forming protective caps on the front side of the substrate chip between adjacent photoelectric conversion modules, each protective cap having inner surfaces and outer surfaces, the inner surfaces together defining a cavity;
forming an encapsulation layer over the front side of the substrate chip, wherein the encapsulation layer fills gaps between the photoelectric conversion modules, and surfaces of the photoelectric conversion modules are exposed from the encapsulation layer;
cutting, from surfaces of the protective caps, the protective caps and the substrate chip so that each cavity is separated into two parts each having an open side;
bonding the backside of the substrate chip to system boards; and
plugging pluggable optical array modules into the cavities from the open sides, thereby integrating the pluggable optical array modules with the substrate chip.

2. The method of claim 1, wherein each of the photoelectric conversion modules comprises a plurality of spaced functional chips, wherein the front side of the semiconductor substrate is exposed between adjacent functional chips, wherein the encapsulation layer also fills the gaps between the functional chips, and wherein the functional chips are connected to the substrate chip by the vias.

3. The method of claim 1, wherein the protective caps and the encapsulation layer are made of the same material.

4. The method of claim 1, wherein the protective caps and the encapsulation layer are made of a material comprising a resin.

5. The method of claim 1, wherein there are optical interconnect trenches in the substrate chip between adjacent photoelectric conversion modules, which are covered by the protective caps.

6. The method of claim 5, wherein the protective caps and the substrate chip are cut from the surfaces of the protective caps so that each cavity is separated into two parts, each of the optical interconnect trenches is also separated into two parts.

7. The method of claim 1, wherein the protective caps and the substrate chip are cut from the surfaces of the protective caps so that each cavity is separated into two equal parts.

8. The method of claim 1, wherein the outer surfaces of each protective cap include three outer wall surfaces, which are perpendicularly joined in succession, and the inner surfaces of each protective cap include three inner wall surfaces, which are perpendicularly joined in succession.

9. The method of claim 1, wherein the backside of the substrate chip is soldered to the system boards with a solder material.

10. The method of claim 1, wherein the protective caps are pluggably attached to optical interconnects between adjacent photoelectric conversion modules.

11. The method of claim 1, wherein the protective caps are fixedly attached to optical interconnects between adjacent photoelectric conversion modules.
